(19) United States
(12) Patent Application Publication
(10) Pub. No.: US 2026/0304932 A1
(43) Pub. Date: Oct. 1, 2026

(54) SEMICONDUCTOR DEVICE INCLUDING INTERNAL SPACER LAYERS

(71) Applicant: Samsung Electronics Co., Ltd., Suwon-si (KR)

(72) Inventors: Youngjun Kim, Suwon-si (KR); Sangjine Park, Suwon-si (KR)

(21) Appl. No.: 19/357,601

(22) Filed: Oct. 14, 2025

(30) Foreign Application Priority Data
Mar. 27, 2025 (KR) 10-2025-0039611

(51) Int. Cl. H10D 84/83; H10D 30/00; H10D 62/10; H10D 62/13; H10D 64/23; H10D 64/66; H10D 30/01; H10D 84/01

(52) U.S. Cl. CPC H10D 84/832; H10D 30/506; H10D 62/102; H10D 62/151; H10D 64/256; H10D 64/675; H10D 84/8312; H10D 30/0191; H10D 84/0147

(57) ABSTRACT

A semiconductor device includes an active region extending in a first direction; a plurality of gate structures including a first gate structure and a second gate structure; a plurality of channel layers including first channel layers and second channel layers; a plurality of source/drain regions including a first source/drain region, a second source/drain region, and a third source/drain region; first internal spacer layers between the first gate structure and the first source/drain region; second internal spacer layers between the first gate structure and the second source/drain region; third internal spacer layers between the second gate structure and the second source/drain region; and fourth internal spacer layers between the second gate structure and the third source/drain region.A central thickness of each of the second internal spacer layers is greater than a central thickness of each of the first internal spacer layers.

### CROSS-REFERENCE TO RELATED APPLICATIONS

This application claims benefit of priority to Korean Patent Application No. 10-2025-0039611 filed on Mar. 27, 2025 in the Korean Intellectual Property Office, the disclosure of which is incorporated herein by reference in its entirety.

### BACKGROUND

The present disclosure relates to a semiconductor device and a method for forming the same.

As demand for high performance, high speed, and/or multifunctionality of semiconductor devices increases, a degree of integration of semiconductor devices is increasing. In manufacturing a semiconductor device with a fine pattern in response to the trend of a high degree of integration of semiconductor devices, it is necessary to implement patterns having a fine width or a fine separation distance. In addition, efforts are being made to develop a semiconductor device including a transistor having a three-dimensional channel structure in order to overcome limitations of operating characteristics due to a decrease in a size of a planar metal oxide semiconductor FET (MOSFET).

### SUMMARY

One of the technical problems to be solved by the present disclosure is to provide a semiconductor device capable of increasing a degree of integration thereof.

One of the technical problems to be solved by the present disclosure is to provide a semiconductor device having improved performance.

One of the technical problems to be solved by the present disclosure is to provide a method for forming the semiconductor device.

As a means for solving the above-described problem, a semiconductor device including a substrate including an active region extending in a first direction; a plurality of gate structures extending on the substrate in a second direction and intersecting the active region, the plurality of gate structures includes a first gate structure and a second gate structure disposed to be spaced apart from each other in the first direction; a plurality of channel layers disposed to be spaced apart from each other on the active region, in a third direction, perpendicular to an upper surface of the substrate, and including first channel layers surrounded by the first gate structure and second channel layers surrounded by the second gate structure; a plurality of source/drain regions disposed in a region in which the active region is recessed, on one side of each of the plurality of gate structures, and including a first source/drain region connected to the first channel layers, a second source/drain region connected to the first channel layers and the second channel layers, and a third source/drain region connected to the second channel layers, first internal spacer layers disposed between the first gate structure and the first source/drain region, below each of the first channel layers on the active region; second internal spacer layers disposed between the first gate structure and the second source/drain region, below each of the first channel layers on the active region; third internal spacer layers disposed between the second gate structure and the second source/drain region, below each of the second channel layers on the active region; and fourth internal spacer layers disposed between the second gate structure and the third source/drain region, below each of the second channel layers on the active region, wherein a central thickness of each of the second internal spacer layers in the first direction is greater than a central thickness of each of the first internal spacer layers in the first direction, and a central thickness of each of the third internal spacer layers in the first direction is greater than a central thickness of each of the fourth internal spacer layers in the first direction, may be provided.

In addition, a semiconductor device including a first source/drain region and a second source/drain region; a plurality of channel layers stacked to be spaced apart from each other in a vertical direction, and connected to the first and second source/drain regions in a first direction, intersecting the vertical direction; a gate electrode surrounding each of the plurality of channel layers in a second direction, intersecting the first direction and the vertical direction; gate dielectric layers disposed between the gate electrode and the plurality of channel layers and disposed between the gate electrode and the first and second source/drain regions; first internal spacer layers disposed between the gate dielectric layers and the first source/drain region; and second internal spacer layers disposed between the gate dielectric layers and the second source/drain region, wherein a minimum thickness of each of the second internal spacer layers in the first direction is greater than a minimum thickness of each of the first internal spacer layers in the first direction, may be provided.

In addition, a semiconductor device including a first source/drain region and a second source/drain region; a plurality of channel layers stacked to be spaced apart from each other in a vertical direction, and connected to the first and second source/drain regions in a first direction, intersecting the vertical direction; a gate electrode surrounding each of the plurality of channel layers in a second direction, intersecting the first direction and the vertical direction; gate dielectric layers disposed between the gate electrode and the plurality of channel layers and disposed between the gate electrode and the first and second source/drain regions; first internal spacer layers disposed between the gate dielectric layers and the first source/drain region; and second internal spacer layers disposed between the gate dielectric layers and the second source/drain region, wherein thicknesses of the second internal spacer layers in the first direction is about 1.1 to about 5 times greater than thicknesses of the first internal spacer layers in the first direction, may be provided.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to some implementations.

FIG. 2 illustrates schematic cross-sectional views of a semiconductor device according to some implementations.

FIG. 3 is a partially enlarged view illustrating a semiconductor device according to some implementations.

FIG. 4 is a partially enlarged view illustrating a semiconductor device according to some implementations.

FIG. 5 is a partially enlarged view illustrating a semiconductor device according to some implementations.

FIG. 6 is a partially enlarged view illustrating a semiconductor device according to some implementations.

FIG. 7 is a schematic cross-sectional view illustrating a semiconductor device according to some implementations.

FIG. 8 is a schematic cross-sectional view illustrating a semiconductor device according to some implementations.

FIGS. 9A to 9K are views illustrating a method of manufacturing a semiconductor device according to example implementations, according to a process sequence.

### DETAILED DESCRIPTION

Hereinafter, preferred implementations will be described with reference to the attached drawings. Unless otherwise specifically stated, in this specification, terms such as ‘on,’ ‘upper portion,’ ‘upper surface,’ ‘below,’ ‘lower portion,’ ‘lower surface,’ ‘side surface,’ or the like may be based on the drawings, and may actually vary depending on a direction in which components are disposed.

Additionally, ordinal numbers such as “first,” “second,” “third,” or the like may be used as labels for specific elements, operations, directions, or the like to distinguish between various elements, operations, directions, or the like. Terms that may not be described in the specification using “first,” “second,” or the like may still be referred to as “first” or “second” in the claims. Additionally, terms that may be referenced by a particular ordinal number (e.g., “first” in a particular claim) may be described elsewhere by a different ordinal number (e.g., “second” in the specification or another claim).

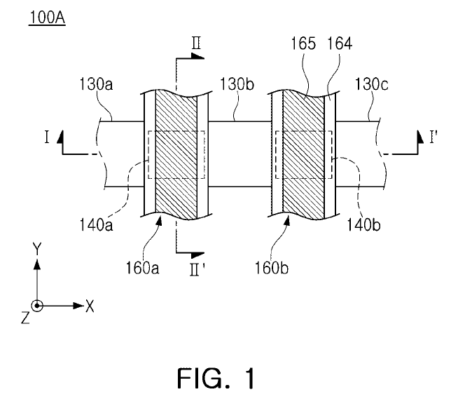

FIG. 1 is a plan view illustrating a semiconductor device 100A according to some implementations. For convenience of explanation, only some components of the semiconductor device 100A are illustrated in FIG. 1.

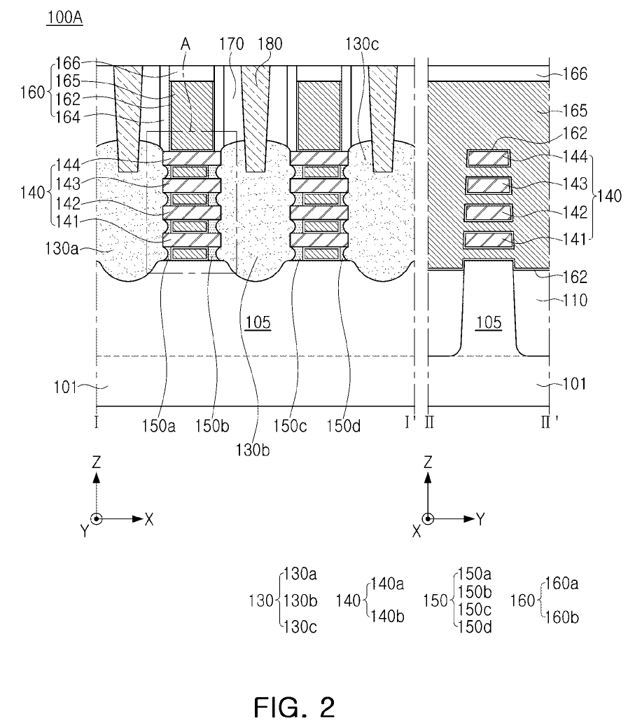

FIG. 2 illustrates schematic cross-sectional views of a semiconductor device 100A according to some implementations. FIG. 2 schematically illustrates cross-sections of the semiconductor device 100A of FIG. 1, taken along lines I-I’ and II-II’.

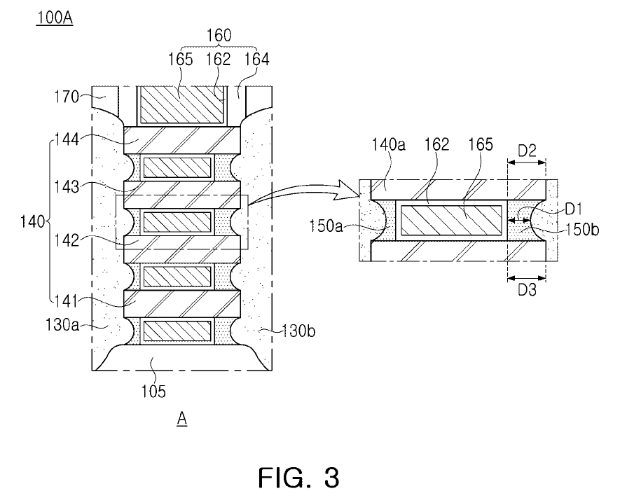

FIG. 3 is a partially enlarged view illustrating a semiconductor device 100A according to some implementations. FIG. 3 illustrates an enlarged view of region ‘A’ of the semiconductor device 100A of FIG. 2.

Referring to FIGS. 1, 2, and 3, a semiconductor device 100A may include a substrate 101 including an active region 105, channel structures 140 including first to fourth channel layers 141, 142, 143, and 144 disposed to be spaced apart from each other vertically on the active region 105, gate structures 160 extending to intersect the active region 105 and respectively including a gate electrode 165, source/drain regions 130 contacting the channel structures 140, internal spacers 150 disposed between the gate structures 160 and the source/drain regions 130 below each of the channel layers 141, 142, 143, and 144, and a contact structure 180 connected to the source/drain regions 130. The internal spacers 150 may include first to fourth internal spacer layers 150a, 150b, 150c, and 150d. The semiconductor device 100A may further include a device isolation layer 110 and an interlayer insulating layer 170.

According to the present disclosure, a thickness of each of the second internal spacer layers 150b in a first direction (e.g., X-direction) may be greater than a thickness of each of the first internal spacer layers 150a in the first direction (e.g., X-direction), and a thickness of each of the third internal spacer layers 150c in the first direction (e.g., X-direction) may be greater than a thickness of each of the fourth internal spacer layers 150d in the first direction (e.g., X-direction).

According to the present disclosure, gate-drain capacitance (Cgd) may be effectively reduced by forming internal spacer layers on a drain side which are thicker than on a source side to increase a separation distance between a gate and a drain.

When the internal spacer layers on the drain side are designed to be thicker while maintaining a length of the gate, a thickness of a spacer on a source side may become somewhat thinner, to increase gate-source capacitance (Cgs), due to characteristics of the source side having a relatively small or constant voltage fluctuation range, influence on switching current and power consumption may be weaker on the source side than on the drain side. Therefore, total effective capacitance (Ceff) may actually decrease.

Furthermore, the device of the present disclosure may not increase a length of the gate (or a length of a channel), but may change only a thickness of the internal spacer layers while maintaining the length of the gate (or the length of the channel), thereby reducing total effective capacitance without deteriorating a degree of integration of a device or channel characteristics. As a result, performance of a transistor may be effectively improved.

In addition, according to the present disclosure, a leakage current caused by a gate-induced drain leakage (GIDL) phenomenon may be prevented or minimized by forming the internal spacer layers on the drain side which are thicker than on a source side to increase a separation distance between a gate and a drain. Therefore, reliability of a transistor may increase and performance thereof may be improved.

Hereinafter, each component of the semiconductor device 100A will be described in detail.

In the semiconductor device 100A, the active region 105 may have a fin structure, and the gate electrode 165 may be disposed between the active region 105 and the channel structure 140, between the first to fourth channel layers 141, 142, 143, and 144 of the channel structure 140, and on the channel structure 140. Therefore, the semiconductor device 100A may include transistors having a MBCFET^{TM} (multi-bridge channel FET) structure, which may be a gate-all-around type of field effect transistor.

The substrate 101 may have an upper surface extending in an X-direction and a Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like.

The substrate 101 may include the active region 105 disposed thereon. The active region 105 may be defined by the device isolation layer 110 in the substrate 101 and may be disposed to extend in the first direction, for example, in the X-direction. Depending on a description manner, it is also possible to describe the active region 105 as a separate configuration from the substrate 101. The active region 105 may partially protrude above the device isolation layer 110, such that an upper surface of the active region 105 may be located on a higher level than an upper surface of the device isolation layer 110. The active region 105 may be formed as a portion of the substrate 101 or may include an epitaxial layer grown from the substrate 101. On both sides of the gate structure 160, the active region 105 may be partially recessed to form recess regions, and a plurality of source/drain regions 130 may be disposed in the recess regions.

In example implementations, the active region 105 may or may not include a well region including impurities. For example, in a p-type transistor (pFET), the well region may include n-type impurities such as phosphorus (P), arsenic (As), or antimony (Sb), and in an n-type transistor (nFET), the well region may include p-type impurities such as boron (B), gallium (Ga), or indium (In). The well region may be located, for example, at a predetermined depth from an upper surface of the active region 105.

The device isolation layer 110 may define the active region 105 in the substrate 101. The device isolation layer 110 may be formed, for example, by a shallow trench isolation (STI) process. The device isolation layer 110 may expose the upper surface of the active region 105 and may also partially expose an upper portion of the active region 105. In some implementations, the device isolation layer 110 may have a curved upper surface to have a higher level toward the active region 105. The device isolation layer 110 may be formed of an insulating material. The device isolation layer 110 may be, for example, an oxide, a nitride, or a combination thereof.

The gate structures 160 may be disposed to extend in a second direction (for example, Y-direction) to intersect the active region 105 and the plurality of channel layers 141, 142, 143, and 144 (hereinafter, referred to as “channel structures”). Functional channel regions of transistors may be formed in the active region 105 and/or the channel structures 140, intersecting the gate electrodes 165 of the gate structures 160. Each of the gate structures 160 may include a gate electrode 165, gate dielectric layers 162 between the gate electrode 165 and the first to fourth channel layers 141, 142, 143, and 144, and gate spacer layers 164 on side surfaces of the gate electrode 165. The gate structures 160 may include a first gate structure 160aand a second gate structure 160b, intersecting the active region 105 to extend in the second direction (e.g., Y-direction), and spaced apart from each other in the first direction (e.g., X-direction).

The gate dielectric layers 162 may be disposed between the active region 105 and the gate electrode 165 and between the channel structure 140 and the gate electrode 165 and may be disposed to cover at least a portion of surfaces of the gate electrode 165. For example, the gate dielectric layers 162 may be disposed to surround all surfaces except for an uppermost surface of the gate electrode 165. The gate dielectric layers 162 may be in contact with the internal spacer layers 150 below each of the plurality of channel layers 141, 142, 143, and 144, and may be spaced apart from the source/drain regions 130 by the internal spacer layers 150. The gate dielectric layers 162 may extend between the gate electrode 165 and the gate spacer layers 164 but are not limited thereto. The gate dielectric layers 162 may include an oxide, a nitride, or a high-κ material. The high-κ material may mean a dielectric material having a higher dielectric constant than a silicon oxide (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). According to some implementations, the gate dielectric layers 162 may be formed as a multilayer film.

The gate electrode 165 may be disposed to fill spaces between the first to fourth channel layers 141, 142, 143, and 144 on the active region 105 and extend onto the channel structure 140. The gate electrode 165 may be separated from the first to fourth channel layers 141, 142, 143, and 144 by gate dielectric layers 162. The gate electrode 165 may include a conductive material, and may include, for example, a metal nitride such as a titanium nitride (TiN), a tantalum nitride (TaN), or a tungsten nitride (WN), and/or a metal material such as aluminum (Al), tungsten (W), or molybdenum (Mo), or a semiconductor material such as doped polysilicon. According to some implementations, the gate electrode 165 may be formed as two or more multilayer structures.

The gate spacer layers 164 may be disposed on both side surfaces of the gate electrode 165 on the channel structure 140. The gate spacer layers 164 may insulate the source/drain regions 130 and the gate electrode 165. The gate spacer layers 164 may be formed as a multilayer structure, according to some implementations. The gate spacer layers 164 may be formed of at least one of an oxide, a nitride, or an oxynitride, and may be formed as, for example, a low-κ film.

The gate structures 160 may further include a gate capping layer 166 on the gate electrode 165. The gate capping layer 166 may extend in the Y-direction along the gate electrode 165. The gate capping layer 166 may include at least one of SiON, SiCN, SiCON, or SiN.

The channel structures 140 may be disposed on the active region 105 in regions in which the active region 105 intersects the gate structures 160. Each of the channel structures 140 may include the first to fourth channel layers 141, 142, 143, and 144, which may be a plurality of channel layers disposed to be spaced apart from each other in the Z-direction. The first to fourth channel layers 141, 142, 143, and 144 may be disposed sequentially from an upper portion, and the first channel layer 141 may be a lowermost channel layer. The channel structures 140 may be connected to the source/drain regions 130. The channel structures 140 may have a width, equal to or similar to the gate structures 160 in the X-direction, and may have a width, equal to or smaller than the active region 105 in the Y-direction. In a cross-section in the Y-direction, among the first to fourth channel layers 141, 142, 143, and 144, a channel layer disposed in a lower portion may have a width, equal to or greater than a width of a channel layer disposed in an upper portion. The number and shapes of channel layers forming a single channel structure 140 may be variously changed in some implementations. For example, one channel structure 140 may include three channel layers, or may include two channel layers, or five or more channel layers. The channel structure 140 may include first channel layers 140adisposed to be surrounded by the first gate structure 160a, and second channel layers 140b disposed to be surrounded by the second gate structure 160b.

The channel structures 140 may be formed of a semiconductor material, and may include, for example, at least one of silicon (Si), silicon germanium (SiGe), or germanium (Ge). The channel structures 140 may be formed of, for example, the same material as the active region 105. In some implementations, the channel structures 140 may also include an impurity region located in a region adjacent to the source/drain regions 130.

The source/drain regions 130 may be disposed in recess regions partially recessing an upper portion of the active region 105 on both sides of the gate structures 160. The recess regions may extend along side surfaces of the channel structures 140 and side surfaces of the gate dielectric layers 162. The source/drain regions 130 may be disposed to cover side surfaces of each of the first to fourth channel layers 141, 142, 143, and 144 of the channel structures 140 in the X-direction. Upper surfaces of the source/drain regions 130 may be located on a level, equal to or higher than lower surfaces of the gate electrodes 165 on the channel structures 140, and the level may be variously changed in some implementations. Side surfaces of the source/drain regions 130 may have a curvature according to the first to fourth channel layers 141, 142, 143, and 144 and the internal spacer layers 150. For example, the side surface of the source/drain regions 130 contacting the channel structures 140 may be flat or may be concave in an inward direction. Specific shapes of the side surfaces of the source/drain regions 130 may not be fixed and may be changed depending on some implementations. The source/drain regions 130 may be an epitaxially grown region and may include a plurality of epitaxial layers. Epitaxially grown surfaces of the source/drain regions 130 may be in contact with the channel structures 140, the internal spacer layers 150, and the interlayer insulating layer 170. The source/drain regions 130 may be disposed in a recess region of the active region 105 on one side of each of the gate structures 160 and may include a first source/drain region 130aconnected to the first channel layers 140a, a second source/drain region 130b connected to the first channel layers 140a and the second channel layers 140b, and a third source/drain region 130c connected to the second channel layers 140b. The first source/drain region 130a, the second source/drain region 130b, and the third source/drain region 130c may be disposed to be spaced apart from each other in the first direction (e.g., X-direction). The first source/drain region 130amay be connected to the first channel layers 140a, the second source/drain region 130b may be connected to the first channel layers 140aand the second channel layers 140b, and the third source/drain region 130c may be connected to the second channel layers 140b.

The source/drain regions 130 may include a semiconductor material, for example, at least one of silicon (Si) or germanium (Ge), and may further include dopants. For example, when the semiconductor device 100A is an nFET, the dopants may be at least one of phosphorus (P), arsenic (As), or antimony (Sb). For example, when the semiconductor device 100A is a pFET, the dopants may be at least one of boron (B), gallium (Ga), or indium (In). According to some implementations, the source/drain regions 130 may be formed as a plurality of epitaxial layers.

The internal spacer layers 150 may be disposed to be parallel to the gate electrode 165 between the first to fourth channel layers 141, 142, 143, and 144 in the Z-direction. The gate electrode 165 may be stably spaced apart from and electrically isolated from the source/drain regions 130 by the internal spacer layers 150.

The internal spacer layers 150 may include first internal spacer layers 150a, second internal spacer layers 150b, third internal spacer layers 150c, and fourth internal spacer layers 150d. The first internal spacer layers 150a may be disposed between the first gate structure 160a and the first source/drain region 130a below each of the first channel layers 140a on the active region 105. The second internal spacer layers 150b may be disposed between the first gate structure 160a and the second source/drain region 130b below each of the first channel layers 140a on the active region 105. The third internal spacer layers 150c may be disposed between the second gate structure 160b and the second source/drain region 130b below each of the second channel layers 140b on the active region 105. The fourth internal spacers 150d may be disposed between the second gate structure 160b and the third source/drain region 130c below each of the second channel layers 140b on the active region 105.

A central thickness of each of the second internal spacer layers 150b in the first direction (e.g., X-direction) may be greater than a central thickness of each of the first internal spacer layers 150a in the first direction (e.g., X-direction). A central thickness of each of the third internal spacer layers 150c in the first direction (e.g., X-direction) may be greater than a central thickness of each of the fourth internal spacer layers 150d in the first direction (e.g., X-direction).

The internal spacer layers 150 may include an outer side surface contacting the source/drain regions 130, and an inner side surface contacting the gate dielectric layers 162 of the gate structures 160. The internal spacer layers 150 may have a shape in which the outer side surface facing the source/drain regions 130 is concavely rounded, inwardly toward the gate electrode 165, but the shape is not limited thereto.

The internal spacer layers 150 may have a shape in which the inner side surface facing the gate dielectric layers 162 is relatively less rounded than the outer side surface. Therefore, the inner side surface of the internal spacer layers 150 may appear to be perpendicular to the upper surface of the substrate 101 but the shape is not limited thereto. Depending on shapes of the source/drain regions 130, a process method and an order of the internal spacer layers 150, or the like, shapes of the internal spacer layers 150 may be modified in various manners.

The internal spacer layers 150 may include at least one of an oxide, a nitride, or an oxynitride, and may be formed as, for example, a low-κ film. In some implementations, the internal spacer layers 150 may include silicon nitride or silicon oxynitride.

As illustrated in FIG. 3, referring mainly to one internal spacer layer of the internal spacer layers 150, an intermediate portion located in a central portion of the one internal spacer layer, a lower portion extending downward from the intermediate portion and having a maximum thickness, greater than a thickness of the intermediate portion, and an upper portion extending upward from the intermediate portion and having a maximum thickness, greater than the thickness of the intermediate portion, may be included.

In the internal spacer layers 150, a thickness of each portion of the one internal spacer layer may mean a thickness in a direction, perpendicular to surfaces of the gate dielectric layers 162. In the present disclosure, a central thickness D1 may mean a thickness of the intermediate portion of the internal spacer layers 150, an upper thickness D2 may mean a thickness of the upper portion of the internal spacer layers 150, and a lower thickness D3 may mean a thickness of the lower portion of the internal spacer layers 150.

In the first direction (e.g., X-direction), the central thickness D1 of each of the internal spacer layers 150 may be smaller than the upper thickness D2 and the lower thickness D3 of each of the internal spacer layers 150. The central thickness D1 of each of the internal spacer layers 150 may be a minimum thickness, and the upper thickness D2 and the lower thickness D3 may be maximum thicknesses. A thickness of each of the second internal spacer layers 150b in the first direction (e.g., X-direction) may be greater than a thickness of each of the first internal spacer layers 150a. A thickness of each of the third internal spacer layers 150c in the first direction (e.g., X-direction) may be greater than a thickness of each of the fourth internal spacer layers 150d in the first direction (e.g., X-direction). The thickness may refer to the central thickness D1 of the internal spacer layers 150 or may refer to a minimum thickness.

According to the present disclosure, the thickness of each of the second internal spacer layers 150b in the first direction (e.g., X-direction) may be greater than the thickness of each of the first internal spacer layers 150a in the first direction (e.g., X-direction), and the thickness of each of the third internal spacer layers 150c in the first direction (e.g., X-direction) may be greater than the thickness of each of the fourth internal spacer layers 150d in the first direction (e.g., X-direction). In some implementations (or for example), the central thickness D1 (or ‘minimum thickness’) of the second internal spacer layers 150b and the third internal spacer layers 150c may be in a range of about 5 nm to about 9 nm. The central thickness D1 (or ‘minimum thickness’) of the first internal spacer layers 150a and the fourth internal spacer layers 150d may be in a range of about 1 nm to about 5 nm.

The thickness of the second internal spacer layers 150b and the third internal spacer layers 150c in the first direction (e.g., X-direction) may be in a range of about 1.1 times to about 5 times the thickness of the first internal spacer layers 150a and the fourth internal spacer layers 150d in the first direction (e.g., X-direction). When the thickness of the second internal spacer layers 150b and the third internal spacer layers 150c in the first direction (e.g., X-direction) is smaller than the above ratio range, an effect of forming the internal spacer layers on one side thicker to reduce gate-drain capacitance and leakage current may be relatively small. When the thickness of the second internal spacer layers 150b and the third internal spacer layers 150c in the first direction (e.g., X-direction) is greater than the above ratio range, the internal spacer on one side may become excessively thick to actually deteriorate performance of the semiconductor device.

The present disclosure encompasses maintaining the length of the gate (or the length of the channel) while making the internal spacer on a first side of the gate thicker relative to the internal spacer on a second opposite side of the gate, thereby reducing total effective capacitance without deteriorating a degree of integration of a device or channel characteristics. That is, the length of the gate does not need to be changed to achieve the reduction in total effective capacitance. In the present disclosure, the length of the channel may mean a gap between the first source/drain region 130a and the second source/drain region 130b, and the length of the gate may mean a gap between the first gate structure 160aand the second gate structure 160b.

In this case, the length of the gate may be, for example, in a range of about 20 nm to about 25 nm, but is not limited thereto, and may be changed depending on a design of the device. In this case, the length of the channel may be, for example, in a range of about 10 nm to about 15 nm, but is not limited thereto, and may be changed depending on a design of the device. In this case, a combined value of the thickness of the second internal spacer layers 150b and the thickness of the first internal spacer layers 150a may be in a range of about 1% to about 50% of the length of the channel. Likewise, a combined value of the thickness of the third internal spacer layers 150c and the thickness of the fourth internal spacer layers 150d may be in a range of about 1% to about 50% of the length of the channel.

Based on the second source/drain region 130b, the first internal spacer layers 150a and the second internal spacer layers 150b may have a symmetrical shape with respect to the third internal spacer layers 150c and the fourth internal spacer layers 150d. In this case, the second source/drain region 130bmay be a drain side of an NMOS transistor, but this region is not limited thereto, and may be a source side depending on a design of the semiconductor device.

For example, a thickness of each of the second internal spacer layers 150b in the first direction may be equal to a thickness of each of the third internal spacer layers 150c in the first direction, and a thickness of each of the first internal spacer layers 150a in the first direction may be equal to a thickness of each of the fourth internal spacer layers 150d in the first direction. Specifically, a central thickness of each of the second internal spacer layers 150b may be equal to a central thickness of each of the third internal spacer layers 150c, and a central thickness of each of the first internal spacer layers 150a may be equal to a central thickness of each of the fourth internal spacer layers 150d. A distance in the first direction (e.g., X-direction) between an inner side surface on which the first internal spacer layers 150a are in contact with the first gate structure 160a and the second source/drain region 130b may be equal to a distance in the first direction (e.g., X-direction) between an inner side surface on which the fourth internal spacer layers 150d are in contact with the second gate structure 160b and the second source/drain region 130b. A distance in the first direction (e.g., X-direction) between an inner side surface on which the second internal spacer layers 150b are in contact with the first gate structure 160a and the second source/drain region 130b may be equal to a distance in the first direction (e.g., X-direction) between an inner side surface on which the third internal spacer layers 150c are in contact with the second gate structure 160b and the second source/drain region 130b.

The interlayer insulating layer 170 may be disposed to cover the source/drain regions 130 and the gate structures 160 and may be disposed to cover the device isolation layer 110. The interlayer insulating layer 170 may include at least one of an oxide, a nitride, or an oxynitride, and may include, for example, a low-κ material. According to some implementations, the interlayer insulating layer 170 may include a plurality of insulating layers.

The contact plugs 180 may penetrate the interlayer insulating layer 170 to be connected to the source/drain regions 130 and may apply an electrical signal to the source/drain regions 130. The contact plugs 180 may have an inclined side surface in which a width of a lower portion is narrower than a width of an upper portion depending on an aspect ratio but their shape is not limited thereto. The contact plugs 180 may extend from an upper portion, for example, below a lower surface of the fourth channel layer 144, which may be an uppermost channel structure 140, but is not limited thereto.

Each of the contact plugs 180 may include a metal silicide layer located on a lower end including a lower surface and may further include a barrier layer forming side surfaces of the contact plug 180 and extending onto an upper surface of the metal silicide layer. The barrier layer may include a metal nitride, such as, for example, a titanium nitride (TiN), a tantalum nitride (TaN), or a tungsten nitride (WN). The contact plugs 180 may include a metal material, such as, for example, aluminum (Al), tungsten (W), molybdenum (Mo), or the like. In example implementations, the number and arrangement of conductive layers constituting the contact plugs 180 may be changed.

An interconnection structure such as a contact plug may be further disposed on the gate electrode 165, and an interconnection structure connected to the contact plugs 180 may be further disposed on the contact plugs 180.

The present disclosure may be implemented in various implementations. For example, shape and thickness conditions of the internal spacer layers may be changed depending on a degree of etching performed in a process. In descriptions of implementations below, any description overlapping the description described above with reference to FIGS. 1 to 3 will be omitted.

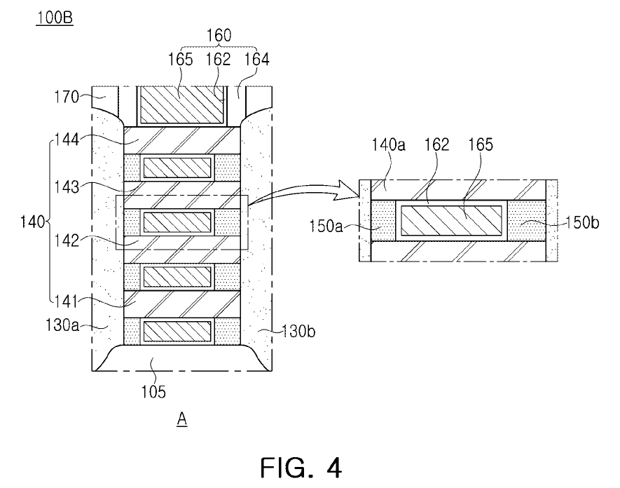

FIG. 4 is a partially enlarged view illustrating a semiconductor device 100B according to some implementations. FIG. 4 illustrates a region corresponding to region ‘A’ of FIG. 2 and illustrates a modified example of FIG. 3.

Referring to FIG. 4, a semiconductor device 100B according to some implementations may have the same or similar features as those described with reference to FIGS. 1, 2, and 3, except that a degree to which outer side surfaces of internal spacer layers 150 are rounded may be changed.

Referring to FIG. 4, the internal spacer layers 150 of the semiconductor device 100B may include outer side surfaces contacting source/drain regions 130, and inner side surfaces contacting gate dielectric layers 162 of gate structures 160.

The internal spacer layers 150 may have a shape in which a degree to which the outer side surfaces facing the source/drain regions 130 are rounded is small. Therefore, the outer side surfaces of the internal spacer layers 150 may appear as a shape perpendicular to an upper surface of a substrate 101. The inner side surfaces of the internal spacer layers 150 facing the gate dielectric layers 162 may have a shape in which a degree to which the inner side surfaces are rounded is small. Therefore, the inner side surfaces of the internal spacer layers 150 may appear as a shape perpendicular to the upper surface of the substrate 101.

Outer side surfaces of first internal spacer layers 150a contacting a first source/drain region 130a may be substantially coplanar with side surfaces of the first channel layers 140a, and outer side surfaces of second internal spacer layers 150b contacting a second source/drain region 130b may be substantially coplanar with the side surfaces of the first channel layers 140a.

As illustrated in FIG. 4, referring to mainly one internal spacer layer of the internal spacer layers 150, an intermediate portion located in a central portion of the one internal spacer layer, a lower portion extending downward from the intermediate portion and having a thickness, equal to a thickness of the intermediate portion, and an upper portion extending upward from the intermediate portion and having a thickness, equal to the thickness of the intermediate portion, may be included.

In the internal spacer layers 150, a thickness of each portion of the one internal spacer layer may mean a thickness in a direction, perpendicular to surfaces of gate dielectric layers 162. In some implementations, thicknesses of the upper portion, the intermediate portion, and the lower portion of the internal spacer layers 150 may be constant in the Z-direction.

Descriptions regarding comparison of the thicknesses described above with reference to FIGS. 1 to 3 will be omitted.

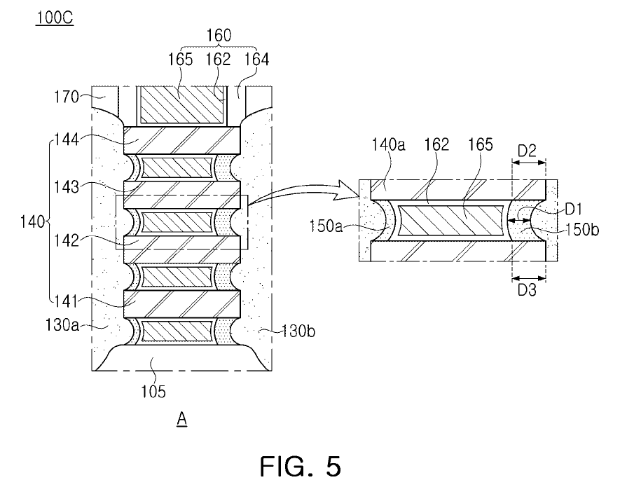

FIG. 5 is a partially enlarged view illustrating a semiconductor device 100C according to some implementations. FIG. 5 illustrates a region corresponding to region ‘A’ of FIG. 2 and illustrates a modified example of FIG. 3.

Referring to FIG. 5, a semiconductor device 100C according to some implementations may have the same or similar features as those described with reference to FIGS. 1, 2, and 3, except that a degree to which inner side surfaces of internal spacer layers 150 are rounded may be changed.

Referring to FIG. 5, the internal spacer layers 150 of the semiconductor device 100C may include outer side surfaces contacting source/drain regions 130, and inner side surfaces contacting gate dielectric layers 162 of gate structures 160.

The internal spacer layers 150 may have a shape in which the outer side surfaces facing the source/drain regions 130 are concavely rounded inwardly toward the gate electrode 165 and may have a shape in which the inner side surfaces facing the gate dielectric layers 162 are concavely rounded inwardly toward the gate electrode 165, but are not limited thereto.

In the first direction (e.g., X-direction), a central thickness D1 of each of the internal spacer layers 150 may be smaller than an upper thickness D2 and a lower thickness D3 of each of the internal spacer layers 150. The central thickness D1 of each of the internal spacer layers 150 may be a minimum thickness, and the upper thickness D2 and the lower thickness D3 may be a maximum thickness.

Shapes, such as a degree to which a side surface of the internal spacer layers is rounded, curvature, or the like may be changed depending on a degree of etching performed in a process. Therefore, the central thickness D1 of each of the internal spacer layers 150 may be greater than the upper thickness D2 and the lower thickness D3 of each of the internal spacer layers 150. In addition, the central thickness D1 of each of the internal spacer layers 150 may be a maximum thickness, and the upper thickness D2 and the lower thickness D3 may be a minimum thickness.

Hereinafter, descriptions regarding comparison of the thicknesses described above with reference to FIGS. 1 to 3 will be omitted.

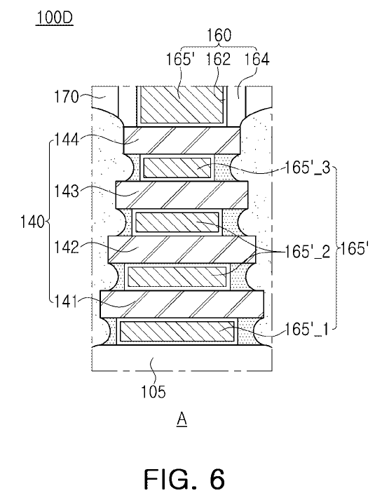

FIG. 6 is a partially enlarged view illustrating a semiconductor device 100D according to some implementations. FIG. 6 illustrates a region corresponding to region ‘A’ of FIG. 2 and illustrates a modified example of FIG. 3.

Referring to FIG. 6, a semiconductor device 100D according to some implementations may have the same or similar features as those described with reference to FIGS. 1, 2, and 3, except that a width of a channel portion in the X-direction gradually increases toward a lower end portion.

In the gate structure 160 described above, the gate electrode (165 of FIG. 2) may be transformed into a gate electrode 165’ of which width in the first direction (e.g., X-direction) increases.

The gate electrode 165’ may include an upper gate portion 165’_3, an intermediate gate portion 165’_2, and a lower gate portion 165’_1. In the gate electrode 165’, the intermediate gate portion 165’_2 may have a width, greater than a width of the intermediate portion of the gate electrode 165 of FIG. 3, corresponding to the intermediate gate portion 165’_2. The lower gate portion 165’_1 may have a width, greater than a width of the lower portion of the gate electrode 165 of FIG. 3, corresponding to the lower gate portion 165’_1. Therefore, as an overall size of the gate electrode 165’ increases, electrical characteristics of the gate electrode of a transistor including the gate electrode 165’ may be improved.

In a semiconductor device 100D of some implementations, even when a width of a channel portion in the X-direction increases, only a width of the gate electrode 165’ increases, and the thickness and ratio of the internal spacer layers 150 may not be changed. Hereinafter, descriptions regarding comparison of the thicknesses described above with reference to FIGS. 1 to 3 will be omitted.

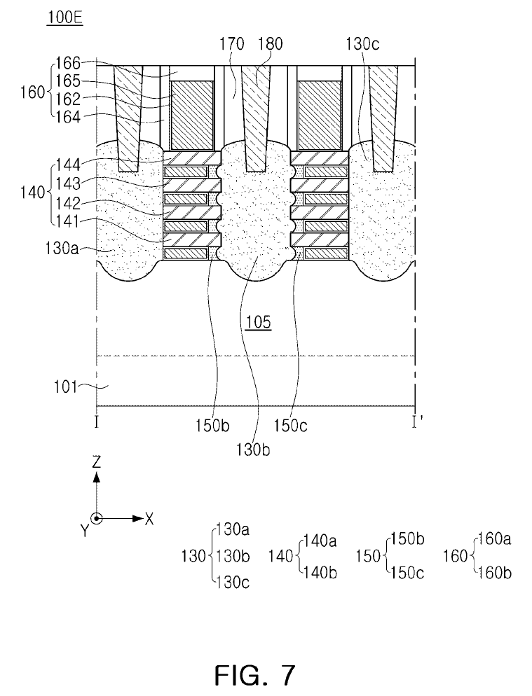

FIG. 7 is a schematic cross-sectional view illustrating a semiconductor device 100E according to some implementations. FIG. 7 illustrates a region corresponding to a cross-section of FIG. 2, taken along line I-I’.

Referring to FIG. 7, a semiconductor device 100E according to some implementations may have the same or similar features as those described with reference to FIGS. 1, 2, and 3, except that first internal spacer layers 150a and fourth internal spacer layers 150d are omitted.

Referring to FIG. 7, the semiconductor device 100E according to some implementations may have a structure in which the first internal spacer layers 150a and the fourth internal spacer layers 150d are omitted, thereby forming an internal spacer only on one side of a gate structure of a transistor. Side surfaces of gate dielectric layers 162 facing source/drain regions 130 may be substantially coplanar with side surfaces of channel structures 140.

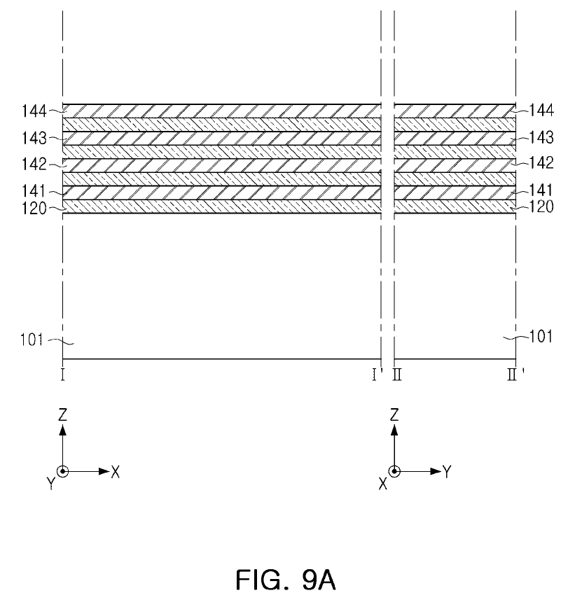

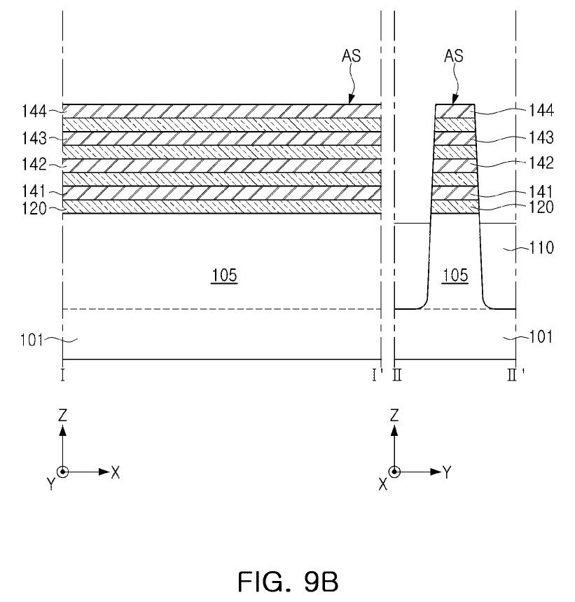

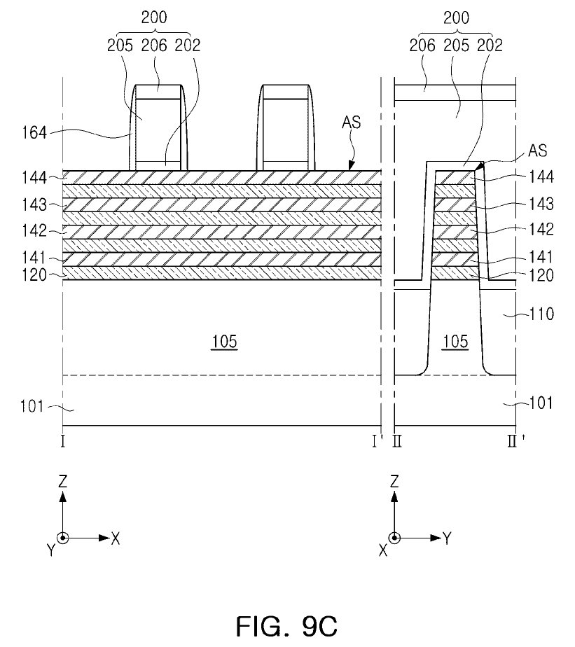

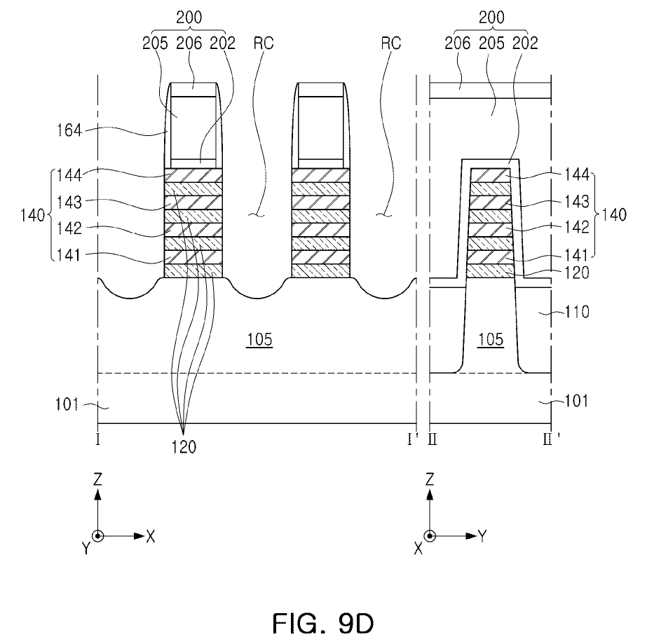

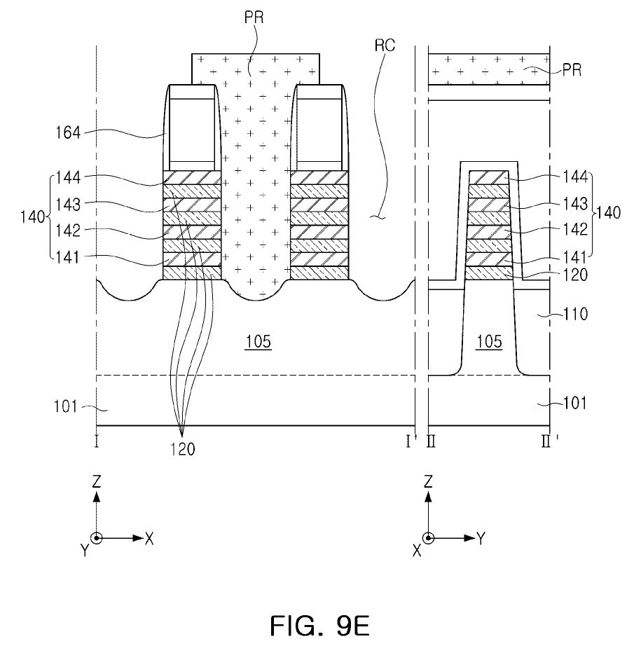

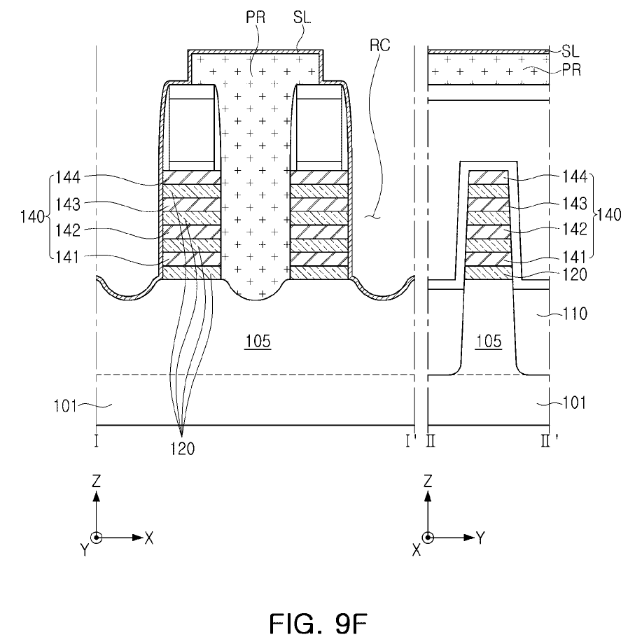

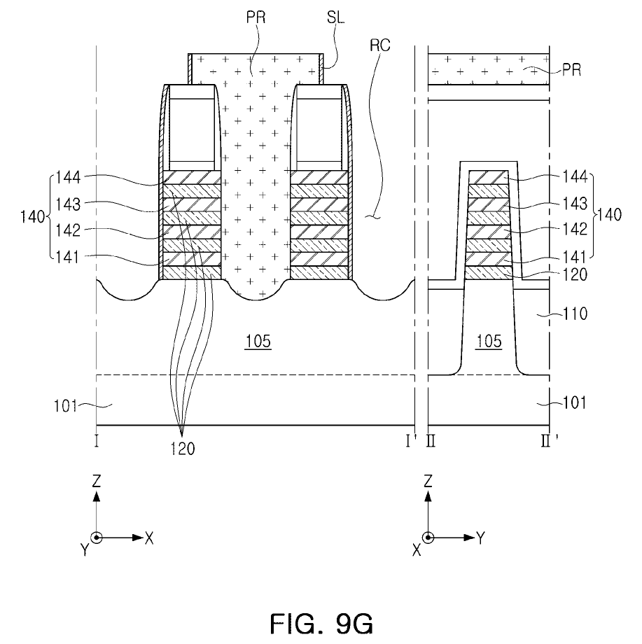

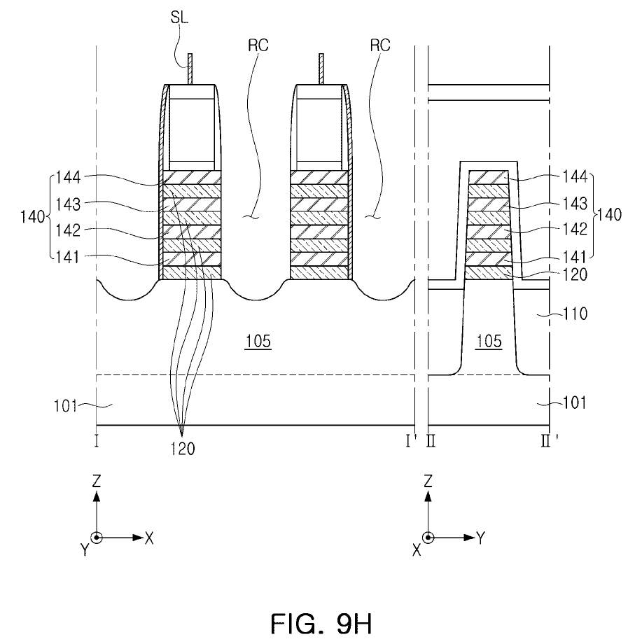

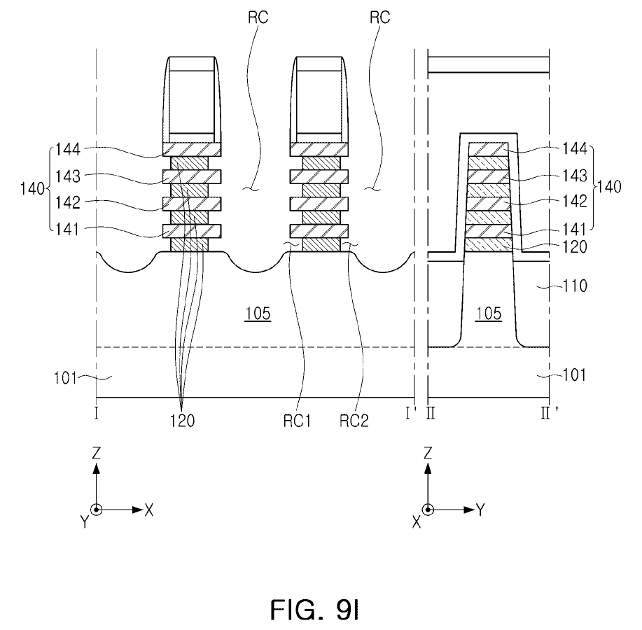

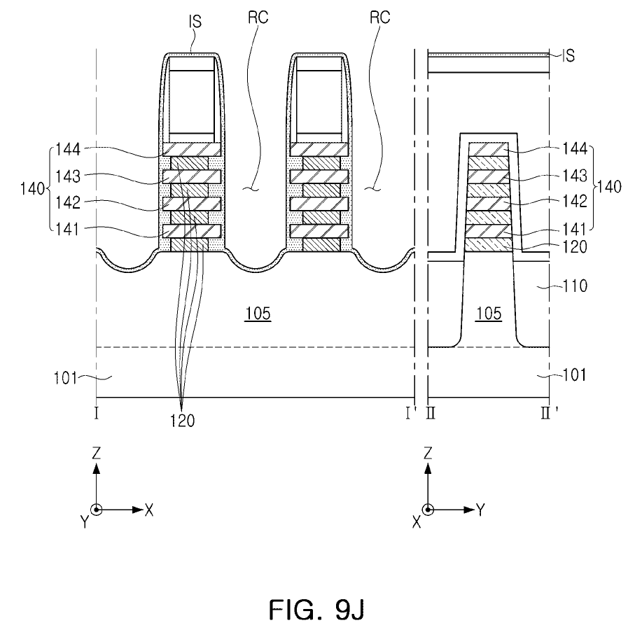

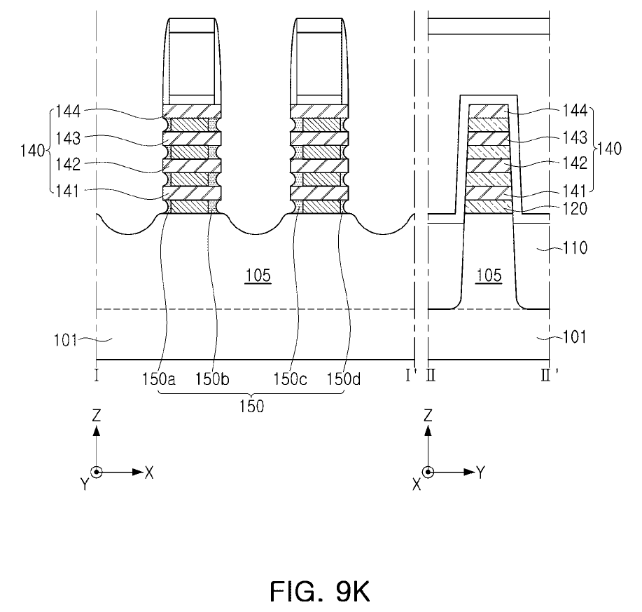

A structure such as the semiconductor device 100E of FIG. 7 may be formed when a thickness of a sacrificial liner layer SL to be formed in FIG. 9F is equal to a thickness of a sacrificial layer 120 to be etched and removed in FIG. 9I. In this case, one side surface of the sacrificial layer 120 may not be further removed inward, and a side surface of the channel structure 140 and a side surface of the sacrificial layer 120 may be substantially coplanar.

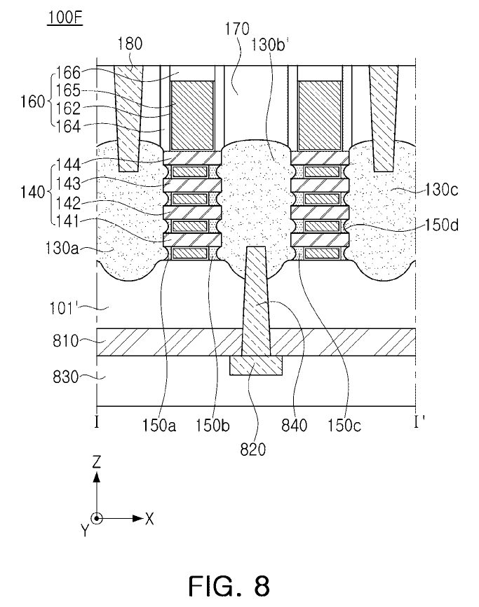

FIG. 8 is a schematic cross-sectional view illustrating a semiconductor device 100F according to some implementations. FIG. 8 illustrates a region corresponding to a cross-section of FIG. 2, taken along line I-I’.

Referring to FIG. 8, the second source/drain region 130b (FIG. 2) may be replaced with a 2nd source/drain region 130b’. The substrate 101 and the active region 105 described in FIG. 2 may be replaced with an insulator body 101’. The insulator body 101’ may include one of silicon oxide, silicon nitride, silicon oxynitride, silicon oxycarbide, or silicon oxycarbonitride.

A semiconductor device 100F may further include a first rear insulating layer 810 below the insulator body 101’, a rear interconnection structure 820 disposed below the first rear insulating layer 810, and a second rear insulating layer 830 covering the rear interconnection structure 820 below the first rear insulating layer 810. The rear interconnection structure 820 may include ruthenium (Ru), molybdenum (Mo), tungsten (W), copper (Cu), a copper-containing alloy, or the like. The first rear insulating layer 810 and the second rear insulating layer 830 may include, for example, at least one of an oxide, a nitride, an oxynitride, or a low-κ dielectric. The insulator body 101’ may include the same material as at least one of the device isolation layer 110 (FIG. 2) or the first rear insulating layer 810. In this case, a boundary between the device isolation layer 110 (FIG. 2) and a layer including the same material as the insulator body 101’, among the first rear insulating layer 810, may not be identified. Therefore, the insulator body 101’ and the device isolation layer 110 may be collectively referred to as a lower insulating layer, and the insulator body 101’ and the first rear insulating layer 810 may be collectively referred to as a lower insulating layer.

At least one of contact plugs 180 (FIG. 2) connected to the source/drain regions 130 described above may be replaced with a rear contact structure 840 penetrating the first rear insulating layer 810 and the insulator body 101’. For example, one of contact plugs 180 may be electrically connected to the first source/drain region 130a and the third source/drain region 130c, the same as those of FIG. 2, and the other may be replaced with a rear contact structure 840 penetrating the first rear insulating layer 810 and the insulator body 101’ and extending into the second source/drain region 130b’. The rear contact structure 840 may be electrically connected to the rear interconnection structure 820.

Each of the rear contact structures 840 may include a metal silicide layer located on an upper side including an upper surface and may further include a barrier layer extending onto a lower surface of the metal silicide layer forming side surfaces of the rear contact structure 840. The barrier layer may include a metal nitride, such as, for example, a titanium nitride (TiN), a tantalum nitride (TaN), or a tungsten nitride (WN). The rear contact structure 840 may include a metal material, such as, for example, aluminum (Al), tungsten (W), molybdenum (Mo), or the like. In example implementations, the number and arrangement of conductive layers constituting the rear contact structure 840 may be variously changed.

FIGS. 9A to 9K are views illustrating a method of manufacturing a semiconductor device according to example implementations, according to a process sequence. FIGS. 9A to 9K illustrate some implementations of a method of manufacturing the semiconductor device of FIG. 2.

Referring to FIG. 9A, sacrificial layers 120 and first to fourth channel layers 141, 142, 143, and 144 may be alternately stacked on a substrate 101.

The sacrificial layers 120 may be layers to be replaced with gate dielectric layers 162 and gate electrodes 165 below the fourth channel layer 144 by a subsequent process, as in FIG. 2. The sacrificial layers 120 may be formed of a material having etch selectivity with respect to the first to fourth channel layers 141, 142, 143, and 144. The first to fourth channel layers 141, 142, 143, and 144 may include a different material from the sacrificial layers 120. The sacrificial layers 120 and the first to fourth channel layers 141, 142, 143, and 144 may include a semiconductor material including, for example, at least one of silicon (Si), silicon germanium (SiGe), or germanium (Ge), but may include different materials, and may or may not include impurities. For example, the sacrificial layers 120 may include silicon germanium (SiGe), and the first to fourth channel layers 141, 142, 143, and 144 may include silicon (Si).

The sacrificial layers 120 and the first to fourth channel layers 141, 142, 143, and 144 may be formed by performing an epitaxial growth process from the stacked structure. The number of layers of the channel layers alternately stacked with the sacrificial layers 120 may be changed in implementations.

Referring to FIG. 9B, the sacrificial layers 120, the first to fourth channel layers 141, 142, 143, and 144, and the substrate 101 may be partially removed to form an active structure AS including an active region 105, and a device isolation layer 110 may be formed.

The active structure AS may include the active region 105, the sacrificial layers 120, and the first to fourth channel layers 141, 142, 143, and 144. The active structure AS may be formed in a linear shape extending in one direction, for example, the X-direction, and may be formed to be spaced apart from an active structure adjacent thereto in the Y-direction. Side surfaces of the active structure AS in the Y-direction may be coplanar with each other and may be located on a straight line.

An insulating material may be filled in a region in which the active region 105, the sacrificial layers 120, and each of the first to fourth channel layers 141, 142, 143, and 144 are partially removed, and then the device isolation layer 110 may be formed by removing a portion of the insulating material such that the active region 105 protrudes. An upper surface of the device isolation layer 110 may be formed to be lower than an upper surface of the active region 105.

Referring to FIG. 9C, sacrificial gate structures 200 and gate spacer layers 164 may be formed on the active structure AS.

Each of the sacrificial gate structures 200 may be a sacrificial structure formed in a region in which gate dielectric layers 162 and gate electrodes 165 are disposed on a channel structure 140 through a subsequent process, as illustrated in FIG. 2. The sacrificial gate structures 200 may have a linear shape extending in one direction while intersecting with the active structure. The sacrificial gate structures 200 may extend, for example, in the Y-direction. Each of the sacrificial gate structures 200 may include first and second sacrificial gate layers 202 and 205 and a mask pattern layer 206, sequentially stacked. The first and second sacrificial gate layers 202 and 205 may be patterned using the mask pattern layer 206.

The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

Gate spacer layers 164 may be formed on both sidewalls of the sacrificial gate structures 200. The gate spacer layers 164 may be formed of a low-κ material, and may include, for example, at least one of SiO, SiN, SiCN, SiOC, SiON, or SiOCN.

Referring to FIG. 9D, the active structure AS exposed from the sacrificial gate structures 200 may be partially removed to form recess regions RC.

Using the sacrificial gate structures 200 and the gate spacer layers 164 as masks, a portion of the exposed sacrificial layers 120 and portions of the first to fourth channel layers 141, 142, 143, and 144 may be removed to form the recess regions RC. By this, the first to fourth channel layers 141, 142, 143, and 144 may form channel structures 140 having a limited length in the X-direction.

Referring to FIG. 9E, a photoresist pattern PR may be formed between the sacrificial gate structures 200 and on portions of upper surfaces of the sacrificial gate structures 200.

A photoresist may be covered on the sacrificial gate structures 200 and the active region 105, and the photoresist pattern PR may be formed through a photolithography process. The photoresist pattern PR may be formed in a recess region RC in which a second source/drain region 130b is formed by a subsequent process. The photoresist pattern PR may prevent the sacrificial liner layer SL from being deposited on one side surface of the covered sacrificial layer 120 by covering the one side surface of the sacrificial layer 120. The photoresist pattern PR may be formed on the upper surfaces of the sacrificial structures 200.

In FIG. 9E, the photoresist pattern PR is illustrated as a single layer, but may be only for convenience of explanation, and is not limited thereto.

The photoresist pattern PR may include an anti-reflection layer to prevent light reflection by the lower film during the photolithography process. The anti-reflection layer may include, for example, bottom anti-reflective coating (BARC) or developable bottom anti-reflective coating (dBARC), but is not limited thereto.

Referring to FIG. 9F, a sacrificial liner layer SL conformally covering the photoresist pattern PR, the sacrificial gate structures 200, and the active region 105 may be deposited.

Specifically, the sacrificial liner layer SL may be deposited on an upper surface and a portion of a side surface of the photoresist pattern PR, a portion of an upper surface and a portion of a side surface of the sacrificial gate structures 200, and a portion of the active region 105.

The sacrificial liner layer SL may be formed of a material having etch selectivity with respect to each of the first to fourth channel layers 141, 142, 143, and 144. The first to fourth channel layers 141, 142, 143, and 144 may include a different material from the sacrificial liner layer SL. The sacrificial liner layer SL and the first to fourth channel layers 141, 142, 143, and 144 may include a semiconductor material including at least one of, for example, silicon (Si), silicon germanium (SiGe), or germanium (Ge), but may include different materials, and may or may not include impurities. For example, the sacrificial liner layer SL may include silicon germanium (SiGe), and the first to fourth channel layers 141, 142, 143, and 144 may include silicon (Si).

A thickness of the sacrificial liner layer SL to be deposited may be a difference between a thickness of each of the second internal spacer layers 150b (FIG. 2) and a thickness of each of the first internal spacer layers 150a (FIG. 2), formed through a subsequent process. When the thickness of the deposited sacrificial liner layer SL is relatively thick, the difference between the thickness of each of the second internal spacer layers 150b (FIG. 2) and the thickness of each of the first internal spacer layers 150a (FIG. 2) will become large. When the thickness of the deposited sacrificial liner layer SL is relatively thin, the difference between the thickness of each of the second internal spacer layers 150b (FIG. 2) and the thickness of each of the first internal spacer layers 150a (FIG. 2) will become small. By controlling the thickness of the deposited sacrificial liner layer SL, the difference between the thickness of the second internal spacer layers 150b (FIG. 2) and the thickness of the first internal spacer layers 150a (FIG. 2) may be controlled.

Likewise, the thickness of the deposited sacrificial liner layer SL may be a difference between a thickness of each of the third internal spacer layers 150c (FIG. 2) and a thickness of each of the fourth internal spacer layers 150d (FIG. 2), formed through a subsequent process. By controlling the thickness of the deposited sacrificial liner layer SL, the difference between the thickness of each of the third internal spacer layers 150c (FIG. 2) and the thickness of each of the fourth internal spacer layers 150d (FIG. 2) may be controlled.

When the thickness of the deposited sacrificial liner layer SL is equal to a thickness of each of the sacrificial layers 120 removed from a side surface in the X-direction by a predetermined depth through a subsequent process, a spacer may not be formed on one side, as in the semiconductor device 100E of FIG. 7.

Referring to FIG. 9G, a portion of an upper surface of the sacrificial liner layer SL may be removed using non-selective etching, thereby exposing the upper surface of the photoresist pattern PR.

Specifically, a portion of the sacrificial liner layer SL deposited and extending in the X-direction on the photoresist pattern PR, a portion of the sacrificial liner layer SL deposited and extending in the X-direction on the sacrificial gate structure 200, and a portion of the sacrificial liner layer SL on the active region 105 may be removed by etching. A portion of the sacrificial liner layer SL deposited and extending in the Z-direction on the side surface of the photoresist pattern PR, and a portion of the sacrificial liner layer SL deposited and extending in the Z-direction on one side surface of the sacrificial gate structure 200 may not be removed. Therefore, the upper surface of the photoresist pattern PR may be exposed.

The etching used in FIG. 9G may be, for example, anisotropic etching, but is not limited thereto.

Referring to FIG. 9H, the exposed photoresist pattern PR may be removed.

To remove the exposed photoresist pattern PR, an ashing and strip process may be used, but is not limited thereto.

The exposed photoresist pattern PR may be removed to form a recess region RC again. A second source/drain pattern 130b (FIG. 2) may be formed in the recess region RC formed again by a subsequent process. The exposed photoresist pattern PR may be removed to expose one side surface of the sacrificial layers 120 not covered by the sacrificial liner layer SL.

Referring to FIG. 9I, a portion of the sacrificial layers 120 and the sacrificial liner layer SL may be removed by a wet etching process.

The sacrificial liner layer SL may be selectively etched with respect to the channel structure 140 by, for example, a wet etching process. The sacrificial layers 120 may be selectively etched with respect to the channel structure 140 by, for example, a wet etching process, and may be removed from side surfaces in the X-direction by a predetermined depth. Portions of the side surfaces of the sacrificial layers 120 covered with the sacrificial liner layer SL may be etched relatively less than portions of the side surfaces of the sacrificial layers 120 not covered with the sacrificial liner layer SL. A first recess region RC1 means a region in which the sacrificial layers 120 on a side on which the sacrificial liner layer SL is not covered may be removed, and a second recess region RC2 means a region in which the sacrificial layers 120 on a side on which the sacrificial liner layer SL is applied may be removed. The first recess region RC1 may have a relatively larger volume removed by the etching process than the second recess region RC2. In this case, a difference in the etched X-direction width of each side surface may be equal to a thickness of the sacrificial liner layer SL.

The side surfaces of the sacrificial layers 120 may appear as vertical to the upper surface of the substrate 101 by lateral etching as described above, but is not limited thereto, and a degree of rounding may be changed depending on a degree of etching. In other implementations, the sacrificial layers 120 may have concave side surfaces inwardly by lateral etching as described above.

Referring to FIG. 9J, an insulating material layer IS conformally covering portions of the sacrificial gate structures 200 and a portion of the active region 105 may be deposited.

The insulating material layer IS may be deposited to fill a region in which the sacrificial layers 120 are partially removed. The insulating material layer IS may include at least one of an oxide, a nitride, or an oxynitride, and may be formed as, for example, a low-κ film. In some implementations, the insulating material layer IS may include silicon nitride or silicon oxynitride.

Referring to FIG. 9K, a portion of the insulating material layer IS may be removed to form internal spacer layers 150.

The insulating material layer IS may be removed by, for example, an etching process by a predetermined thickness. Therefore, side surfaces of the internal spacer layers 150 may have concave shapes inwardly by the etching process. In other implementations, outer side surfaces of the internal spacer layers 150 may have shapes, perpendicular to the upper surface of the substrate 101 by the etching process.

Next, referring to FIG. 2 together, source/drain regions 130 may be formed in the recess region RC. Thereafter, an interlayer insulating layer 170 may be formed, and the sacrificial gate structures 200 and the sacrificial layers 120 may be removed. Thereafter, gate structures 160 may be formed. The interlayer insulating layer 170 may be further formed on the gate structure 160. Thereafter, contact plugs 180 may be formed. The interlayer insulating layer 170 may be patterned to form contact holes exposing the source/drain regions 130. Next, a conductive material may be filled into the contact holes to form the contact plugs 180. Specifically, a material forming a barrier layer may be deposited in the contact holes, and then a silicide process may be performed to form a metal-semiconductor compound layer such as a silicide layer on a lower end. Next, a conductive material may be deposited to fill the contact holes to form the contact plugs 180. Thus, the semiconductor device 100A of FIGS. 1 to 3 may be manufactured.

According to implementations of the present disclosure, gate-drain capacitance (Cgd) may be effectively reduced by forming the internal spacer layers on the drain side which are thicker than on a source side to increase a separation distance between a gate and a drain.

According to some implementations of the present disclosure, a leakage current caused by a GIDL phenomenon may be prevented or minimized by forming the internal spacer layers on the drain side which are thicker than on a source side to increase a separation distance between a gate and a drain. Therefore, reliability of a transistor may increase and performance thereof may be improved.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

As a means for solving the above-described problem, a method for manufacturing a semiconductor device including alternately stacking sacrificial layers and channel layers on a substrate; forming an active structure including an active region by partially removing the sacrificial layers, the channel layers, and the substrate; forming sacrificial gate structures on the active structure and intersecting the active structure; forming a recess region by partially removing the active structure on at least one side of the sacrificial gate structures; forming a photoresist pattern between the sacrificial gate structures and on portions of upper surfaces of the sacrificial gate structures; depositing a sacrificial liner layer conformally covering the photoresist pattern, the sacrificial gate structures, and the active region; exposing an upper surface of the photoresist pattern by partially removing an upper surface of the sacrificial liner layer using non-selective etching; removing the exposed photoresist pattern; removing portions of the sacrificial layers and the sacrificial liner layer by a wet etching process; depositing an insulating material layer conformally covering the sacrificial gate structures and a portion of the active region, and forming internal spacer layers by removing a portion of the insulating material layer.

In this case, a method for manufacturing a semiconductor device in which the sacrificial liner layer includes a material having etch selectivity with respect to each of the channel layers, may be provided.

In this case, a method for manufacturing a semiconductor device in which the sacrificial liner layer includes a semiconductor material including at least one of silicon (Si), silicon germanium (SiGe), or germanium (Ge), and includes a different material from the channel layers, may be provided.

In this case, a method for manufacturing a semiconductor device in which the exposing an upper surface of the photoresist pattern by partially removing an upper surface of the sacrificial liner layer using non-selective etching includes partially removing the upper surface of the sacrificial liner layer using anisotropic etching, may be provided.

In this case, a method for manufacturing a semiconductor device in which the removing portions of the sacrificial layers and the sacrificial liner layer by a wet etching process includes a process in which the sacrificial liner layer is selectively etched with respect to the channel layers by the wet etching process, may be provided.

In this case, a method for manufacturing a semiconductor device in which the removing portions of the sacrificial layers and the sacrificial liner layer by a wet etching process includes a process in which portions of the sacrificial layers are selectively etched with respect to the channel layers by the wet etching process, may be provided.

In this case, a method for manufacturing a semiconductor device in which the insulating material layer includes silicon nitride or silicon oxynitride, may be provided.

In this case, a method for manufacturing a semiconductor device in which the internal spacer layers include first to fourth internal spacer layers, and a central thickness of each of the second internal spacer layers in the first direction is greater than a central thickness of each of the first internal spacer layers in the first direction, and a central thickness of each of the third internal spacer layers in the first direction is greater than a central thickness of each of the fourth internal spacer layers in the first direction, may be provided.

In this case, a method for manufacturing a semiconductor device in which the internal spacer layers include first to fourth internal spacer layers, and a thickness of each of the second internal spacer layers in the first direction is in a range of about 1.1 to about 5 times greater than a thickness of each of the first internal spacer layers in the first direction, may be provided.

In this case, a method for manufacturing a semiconductor device in which the internal spacer layers include first to fourth internal spacer layers, and the central thickness of each of the second internal spacer layers is equal to the central thickness of each of the third internal spacer layers, may be provided.

While example implementations have been illustrated and described above, it will be apparent to those skilled in the art that modifications and variations could be made without departing from the scope of the present disclosure as defined by the appended claims.

What is claimed is:

1. A semiconductor device comprising:
a substrate including an active region extending in a first direction;
a plurality of gate structures extending on the substrate in a second direction and intersecting the active region, the plurality of gate structures including a first gate structure and a second gate structure spaced apart from each other in the first direction;
a plurality of channel layers on the active region and spaced apart from each other in a third direction that is perpendicular to an upper surface of the substrate, wherein the plurality of channel layers comprise first channel layers surrounded by the first gate structure and second channel layers surrounded by the second gate structure;
a plurality of source/drain regions in a region in which the active region is recessed, on a first side of each of the plurality of gate structures, wherein the plurality of source/drain regions comprise
a first source/drain region connected to the first channel layers,
a second source/drain region connected to the first channel layers and the second channel layers, and
a third source/drain region connected to the second channel layers;
first internal spacer layers between the first gate structure and the first source/drain region, wherein the first internal spacer layers are below each of the first channel layers on the active region;
second internal spacer layers between the first gate structure and the second source/drain region, wherein the second internal spacer layers are below each of the first channel layers on the active region;
third internal spacer layers between the second gate structure and the second source/drain region, wherein the third internal spacer layers are below each of the second channel layers on the active region; and
fourth internal spacer layers between the second gate structure and the third source/drain region, wherein the fourth internal spacer layers are below each of the second channel layers on the active region,
wherein a central thickness of each of the second internal spacer layers in the first direction is greater than a central thickness of each of the first internal spacer layers in the first direction, and
a central thickness of each of the third internal spacer layers in the first direction is greater than a central thickness of each of the fourth internal spacer layers in the first direction.

2. The semiconductor device of claim 1, wherein the central thickness of each of the second internal spacer layers is equal to the central thickness of each of the third internal spacer layers.

3. The semiconductor device of claim 1, wherein the central thickness of each of the first internal spacer layers is equal to the central thickness of each of the fourth internal spacer layers.

4. The semiconductor device of claim 1, wherein a distance in the first direction between an inner side surface on which the first internal spacer layers are in contact with the first gate structure and the second source/drain region is equal to a distance in the first direction between an inner side surface on which the fourth internal spacer layers are in contact with the second gate structure and the second source/drain region.

5. The semiconductor device of claim 1, wherein the central thickness of each of the second internal spacer layers is in a range of about 1.1 to about 5 times the central thickness of each of the first internal spacer layers.

6. The semiconductor device of claim 1, wherein the central thickness of each of the third internal spacer layers is in a range of about 1.1 to about 5 times the central thickness of each of the fourth internal spacer layers.

7. The semiconductor device of claim 1, wherein a gap between the first gate structure and the second gate structure is about 20 nm to about 25 nm.

8. The semiconductor device of claim 1, wherein the central thickness of each of the first internal spacer layers and the central thickness of each of the fourth internal spacer layers is about 1 nm to about 5 nm.

9. A semiconductor device comprising:
a first source/drain region and a second source/drain region;
a plurality of channel layers stacked and spaced apart from each other in a vertical direction, and connected to the first and second source/drain regions in a first direction that intersects the vertical direction;
a gate electrode surrounding each of the plurality of channel layers in a second direction that intersects the first direction and the vertical direction;
gate dielectric layers between the gate electrode and the plurality of channel layers and between the gate electrode and the first and second source/drain regions;
first internal spacer layers between the gate dielectric layers and the first source/drain region; and
second internal spacer layers between the gate dielectric layers and the second source/drain region,
wherein a minimum thickness of each of the second internal spacer layers in the first direction is greater than a minimum thickness of each of the first internal spacer layers in the first direction.

10. The semiconductor device of claim 9, wherein the minimum thickness of each of the second internal spacer layers in the first direction is about 5 nm to about 9 nm.

11. The semiconductor device of claim 9, wherein the minimum thickness of each of the first internal spacer layers in the first direction is about 1 nm to about 5 nm.

12. The semiconductor device of claim 9, wherein a gap between the first source/drain region and the second source/drain region is about 10 nm to about 15 nm.

13. The semiconductor device of claim 9, wherein the first internal spacer layers and the second internal spacer layers include silicon nitride or silicon oxynitride.

14. The semiconductor device of claim 9, wherein outer side surfaces of the first internal spacer layers contacting the first source/drain region are concave in an inward direction toward the gate electrode, and
outer side surfaces of the second internal spacer layers contacting the second source/drain region are concave in an inward direction toward the gate electrode.

15. The semiconductor device of claim 9, wherein outer side surfaces of the first internal spacer layers contacting the first source/drain region are coplanar with side surfaces of the plurality of channel layers, and
outer side surfaces of the second internal spacer layers contacting the second source/drain region are coplanar with the side surfaces of the plurality of channel layers.

16. The semiconductor device of claim 9, wherein inner side surfaces of the first internal spacer layers contacting the gate dielectric layers are concave in an inward direction toward the gate electrode, and
inner side surfaces of the second internal spacer layers contacting the gate dielectric layers are concave in an inward direction toward the gate electrode.

17. The semiconductor device of claim 9, wherein a first gap between inner side surfaces of the first internal spacer layers contacting the gate dielectric layers and the first source/drain region is smaller than a second gap between inner side surfaces of the second internal spacer layers contacting the gate dielectric layers and the second source/drain region.

18. A semiconductor device comprising:
a first source/drain region and a second source/drain region;
a plurality of channel layers stacked and spaced apart from each other in a vertical direction, and connected to the first and second source/drain regions in a first direction that intersects the vertical direction;
a gate electrode surrounding each of the plurality of channel layers in a second direction that intersects the first direction and the vertical direction;
gate dielectric layers between the gate electrode and the plurality of channel layers and between the gate electrode and the first and second source/drain regions;
first internal spacer layers between the gate dielectric layers and the first source/drain region; and
second internal spacer layers between the gate dielectric layers and the second source/drain region,
wherein thicknesses of the second internal spacer layers in the first direction is about 1.1 to about 5 times greater than thicknesses of the first internal spacer layers in the first direction.

19. The semiconductor device of claim 18, wherein a sum of the thicknesses of the second internal spacer layers and the thicknesses of the first internal spacer layers is in a range of about 1% to about 50% of a gap between the first source/drain region and the second source/drain region.

20. The semiconductor device of claim 18, wherein each of the thicknesses of the second internal spacer layers in the first direction is about 5 nm to about 9 nm.
